(19) United States
(12) Patent Application Publication
(10) Pub. No.: US 2022/0325404 A1
(43) Pub. Date: Oct. 13, 2022

(54) METHOD FOR COLOURING A METAL AND COLOURED METAL

(71) Applicant: Comadur SA, Le Locle (CH)

(72) Inventors: Pierry Vuille, Les Emibois (CH); Julien Meier, Hauterive (CH); Alexis Boulmay, Valdahon (FR)

(73) Assignee: Comadur SA, Le Locle (CH)

(21) Appl. No.: 17/655,593

(22) Filed: Mar. 21, 2022

(30) Foreign Application Priority Data
Apr. 8, 2021 (EP) 21167303.3

(51) Int. Cl. C23C 14/48; C23C 14/00; C23C 14/58

(52) U.S. Cl. CPC C23C 14/48; C23C 14/0015; C23C 14/582

(57) ABSTRACT

A method for colouring a part to be treated made of metal, this method including the step of implanting mono- or multi-charged ions in a surface layer of the part to be treated by directing towards this part to be treated a mono- or multi-charged ion beam produced by a source of mono- or multi-charged ions, the part to be treated changing colour under the effect of this ion implantation. A coloured metal can be obtained with the above method.

### TECHNICAL FIELD OF THE INVENTION

The present invention relates to a method for colouring a metal part, in particular a metal part embedded in a ceramic material. The present invention also relates to a coloured metal part obtained using this colouring method.

### TECHNOLOGICAL BACKGROUND

Many metal colouring methods are already known in the prior art. One of these methods, for example, allows to colour aluminium. It is indeed known that raw aluminium is naturally and uncontrollably coloured by oxidation, causing the appearance of stains or marks on the surfaces of the aluminium part in question. To solve this problem, it is possible to oxidise an aluminium part artificially, in order to make its appearance uniform and aesthetic. This technique of controlled oxidation of aluminium is known as anodisation. Anodisation is an electrochemical surface treatment method for aluminium which aims at creating an oxide layer on the surface of an aluminium part. For this purpose, the aluminium part is immersed in a bath wherein an electrolyte containing sulphuric acid is dispersed. By circulating a direct current in this bath, a porous oxide layer is formed on the surface of the aluminium part, the thickness of said porous oxide layer is typically of the order of a few tens of micrometres. This very hard oxide layer protects the surface of the aluminium part against corrosion and can then, due to its porosity, be coloured by trapping a dye in the material.

At the British Museum in London, it is possible to admire the cup of Lycurgus, named after the mythical legislator of Sparta whom it represents. Made in the 4th century B.C. by Roman glassmakers, this cup appears green when lit from the front, and red when lit from behind. This dichroism is due to the presence in the glass of small proportions of gold and silver nanoparticles which give rise to surface phenomena of the plasmonic type. The surface plasmonic phenomenon is observed when all the free electrons of a metal exposed to the same electromagnetic field of wavelength A much greater than the size of the metal particles oscillate collectively and in phase. Metallic nanoparticles exposed to light radiation thus have light scattering properties due to excited plasmonic oscillations. These properties depend on the shape of the particles, their size, their nature and the medium wherein they are dispersed.

The production of colours on metals using the plasmonic effect is of great interest because of its durability as evidenced by the Lycurgus cup, and the possibility of avoiding inks, paints or pigments. A technique for colouring metals by exploiting plasmons has been proposed by a team of Canadian researchers. This technique consists in creating nanostructures controlled by means of a laser beam on the surface of gold, silver, copper or aluminium parts. To achieve this result, the metal parts were treated with bursts of laser pulses produced by a laser emitting in the near infrared at a wavelength of 1.064 μm. The duration of a laser pulse is 10⁻¹² s, and each burst of pulses is separated from the next by equal time intervals. To allow the laser beam to follow the entire image that is to be created on the surface of the metal part, the displacement of this laser beam is ensured by a set of servo-controlled mirrors controlled by a computer. These laser pulses thus create nanoparticles on the surface of the treated metal part and allow to obtain a very complete range of colours.

### SUMMARY OF THE INVENTION

The present invention aims at providing a new technique for colouring metals.

To this end, the present invention relates to a method for colouring a part to be treated made of metal, this method comprising the step which consists in implanting mono- or multi-charged ions in a surface layer of the part to be treated by directing towards this part to be treated a mono- or multi-charged ion beam produced by a source of mono- or multi-charged ions, the part to be treated changing colour under the effect of this ion implantation.

According to special embodiments of the invention:
the mono- or multi-charged ion source is an ECR ion source;
the part to be treated is fixed on a support part insensitive to the ion implantation treatment;
the support part is a ceramic part;
the support part is an external part;
the external part is intended for watchmaking or jewellery;
the external part is selected from the group formed by a watch middle, a watch case back, a watch bezel, a watch dial, a watch bracelet or jewel link, a bridge or a plate of a watch movement, watch hands and a ring;
the metal from which the part to be treated is made is selected from the group of precious metals formed by gold, silver, platinum, palladium, ruthenium, iridium and alloys of these precious metals;
the part to be treated is made using copper, aluminium, zirconium, titanium or an alloy of these metals;
the material to be ionised is selected from the group formed by carbon, nitrogen, oxygen, helium and argon;
mono- or multi-charged ions are accelerated under voltages comprised between 12.5 kV and 47.5 kV, the ion beam power is comprised between 4 mA and 15 mA and the implanted ion dose is comprised between 5·10¹⁵ ions·cm⁻² and 75·10¹⁶ ions·cm⁻²;
the part to be treated is placed in a vacuum chamber into which the mono- or multi-charged ion beam is injected;
after the ion implantation treatment, the part to be treated is subjected to an annealing heat treatment.

The invention also relates to a coloured metal part using the colouring method according to the invention.

Thanks to these features, the present invention provides a method for colouring metal parts which are massive or fixed by any appropriate means on a support part. It has indeed been realised that by appropriately bombarding a metal part with an ion beam, it is possible to modify the colour of this metal part in a controlled and reproducible manner. This method is particularly interesting in the case where the metal parts are fixed on a support part. Indeed, provided that the support part is insensitive to ion bombardment, it is possible to modify the colour of the metal parts without any particular precautions; in particular, long and tedious masking operations are avoided. The method according to the invention thus finds all its interest in particular in the fields of watchmaking and jewellery by allowing to colour, for example, metallic inclusions such as hour indexes fixed on a ceramic part such as a watch bezel. Furthermore, the method according to the invention is easy and quick to implement and does not involve any polluting or toxic product.

### BRIEF DESCRIPTION OF FIGURES

Other features and advantages of the present invention will emerge more clearly from the detailed description which follows of an embodiment of the method according to the invention, this example being given in a purely illustrative and non-limiting manner only in connection with the appended drawing on which:

FIG. 1 is a schematic representation of an ion source of the ECR electron cyclotron resonance type;

FIG. 2 is a schematic representation of an ion implantation installation for implementing the method according to the invention, and

FIGS. 3A and 3B schematically illustrate the change in colour of the part to be treated once it has been subjected to the ion implantation method.

### DETAILED DESCRIPTION OF THE INVENTION

The present invention proceeds from the general inventive idea which consists in bombarding a solid metal part or attached to the surface of a support part by means of a mono- or multi-charged ion beam in order to modify the colour of the metal part thus bombarded. Thanks to these features, the present invention provides a method for colouring metal parts which does not use toxic or polluting products and which is therefore simple and quick to implement. Moreover, in the case where the metal part is attached to a support part, provided that the material from which the support part is made is insensitive to ion bombardment, it is possible to modify the colour of the bombarded metal part without being obliged to carry out long and tedious masking operations.

For the implementation of the method according to the invention, it is advantageous to use a source of mono- or multi-charged ions of the electron cyclotron resonance type. Also known as ECR, such an installation makes use of the cyclotron resonance of electrons to create a plasma. A volume of low pressure gas is ionised by means of microwaves injected at a frequency corresponding to the electron cyclotron resonance defined by a magnetic field applied to a region located inside the volume of gas to be ionised. The microwaves heat the free electrons present in the volume of gas to be ionised. These free electrons, under the effect of thermal agitation, will collide with the atoms or gas molecules and cause their ionisation. The ions produced correspond to the type of gas used. This gas can be pure or compound. It can also be a vapour obtained from a solid or liquid material. The ECR ion source is able to produce mono-charged ions, that is to say ions with a degree of ionisation equal to +1, or multi-charged ions, that is to say ions whose degree of ionisation is greater than +1. The ion beam can also correspond to a mixture of mono- and multi-charged ions.

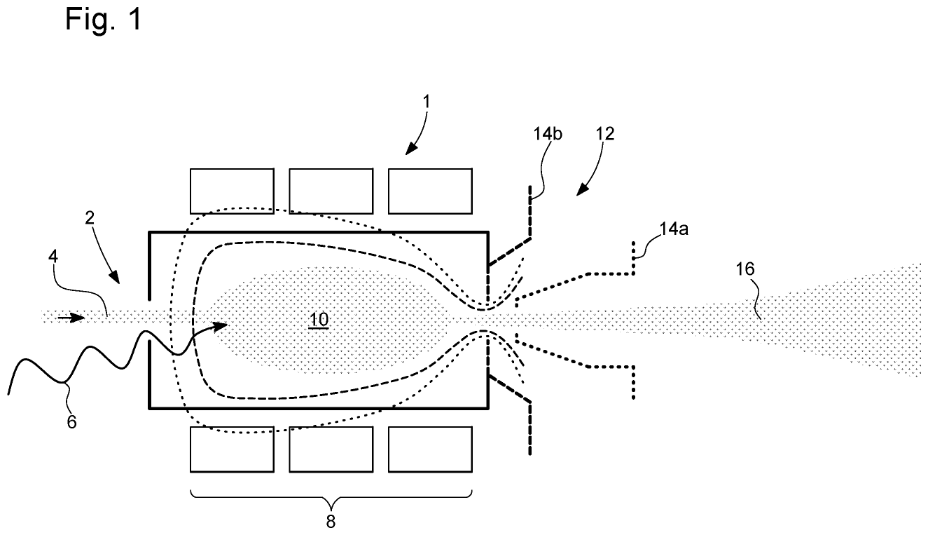

An ion source of the ECR electron cyclotron resonance type is schematically illustrated in FIG. 1 appended to this patent application. Designated as a whole by the general reference numeral 1, this ECR ion source comprises an injection stage 2 into which a volume 4 of a gas to be ionised and a microwave 6 are introduced, a magnetic confinement stage 8 wherein a plasma 10 is created, and an extraction stage 12 which allows to extract and accelerate the ions from the plasma 10 by means of an anode 14a and a cathode 14b between which a high voltage is applied. An ion beam 16 produced at the output of the ECR ion source 1 strikes a surface 18 of a part to be treated 20 and penetrates into the surface of the part to be treated 20.

The part to be treated 20 is a metal part. The metal from which the part to be treated is made is preferably but in a non-limiting manner selected from the group of precious metals formed by gold, silver, platinum, palladium, ruthenium, iridium and alloys of these precious metals. According to another particular embodiment of the invention, the part to be treated can be made using copper, aluminium, zirconium, titanium or an alloy of these metals.

Preferably, but not exclusively, the material to be ionised is selected from the group formed by carbon, nitrogen, oxygen, helium and argon, and the mono- or multi-charged ions are accelerated under voltages comprised between 12.5 kV and 47.5 kV. The ion beam 16 power is comprised between 4 mA and 15 mA and the implanted ion dose is comprised between 5·10¹⁵ ions·cm⁻² and 75·10¹⁶ ions·cm⁻². The ion implantation method is interrupted when the desired colour is observed.

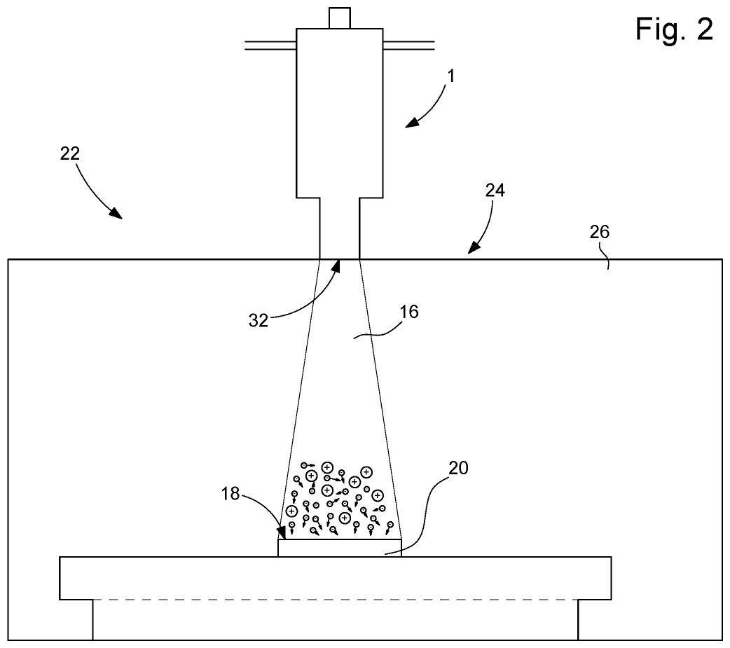

An ion implantation installation allowing the implementation of the method according to the invention is shown schematically in FIG. 2. Designated as a whole by the general reference numeral 22, this ion implantation installation comprises a vacuum chamber 24 in a sealed enclosure 26 of which is placed the part to be treated 20 which is intended to be subjected to the ion implantation method.

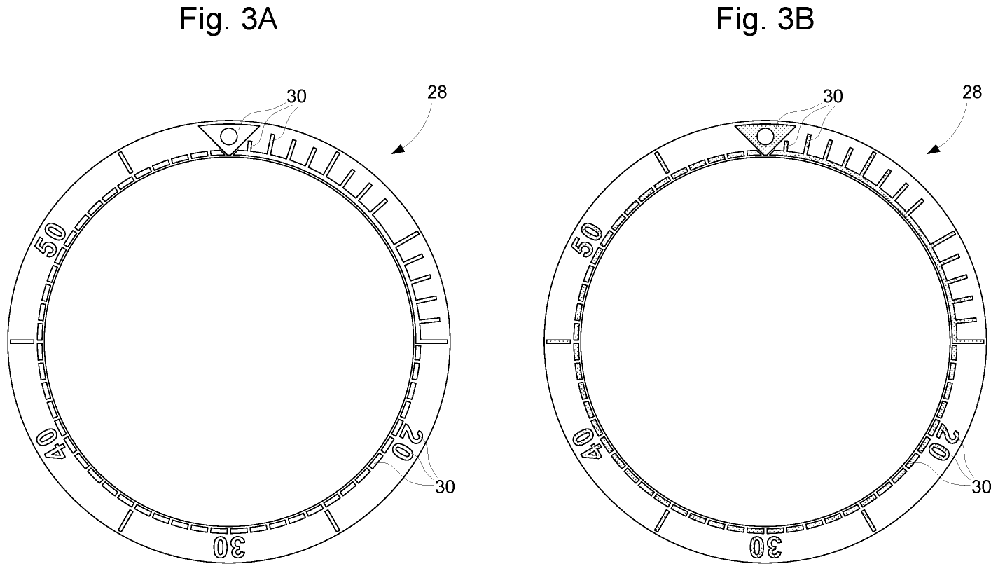

The part to be treated 20 can be massive. It can also be an external part, in particular for watchmaking or jewellery, such as a bezel 28 for a watch. In a particular exemplary embodiment, this bezel 28 is made of a ceramic material and receives metal inserts 30 in recesses made on its surface. These metal inserts 30, whose colour is to be changed, form for example on the surface of the bezel 28 a succession of numbers and indexes which may vary by their shapes and/or their dimensions (see FIG. 3A).

The ion source, here the ECR 1 ion source, is sealingly fixed to the sealed enclosure 26 of the vacuum chamber 24, facing an opening 32 formed in this sealed enclosure 26. This ECR ion source 1, of a type identical to that described above, is oriented so that the mono- or multi-charged ion beam 16 that it produces propagates in the sealed enclosure 26 and strikes the surface of the part to be treated 20. The mono- or multi-charged ions which strike the part to be treated 20 penetrate more or less deeply into the surface of this part to be treated 20 and cause the latter to change colour.

A few numerical examples of the implementation of the method according to the invention are given below, applied to a ceramic bezel 28 with metal inserts 30.

In the case where the metal inserts 30 are made of an alloy of zirconium and aluminium, the treatment of these metal inserts 30 by means of a beam of nitrogen ions with a power of 7 mA accelerated under a voltage of 35 kV has allowed to give these metal inserts 30 a blue colour when the ion implantation dose was 50·10¹⁶ ions·cm⁻².

In the case where the metal inserts 30 are made of titanium, the treatment of these metal inserts 30 by means of a nitrogen ion beam with a power of 6 mA accelerated under a voltage of 37.5 kV has allowed to give these metal inserts 30 a gold colour when the ion implantation dose was 25·10¹⁶ ions·cm⁻².

In the case where the metal inserts 30 are made of titanium, the treatment of these metal inserts 30 by means of a beam of nitrogen ions with a power of 6 mA accelerated under a voltage of 20.0 kV has allowed to give these metal inserts 30 a blue colour when the ion implantation dose was 25·10¹⁶ ions·cm⁻².

In the case where the metal inserts 30 are made of titanium, the treatment of these metal inserts 30 by means of a beam of oxygen ions with a power of 4 mA accelerated under a voltage of 12.5 kV has allowed to give these metal inserts 30 a violet colour when the ion implantation dose was 25·10¹⁶ ions·cm⁻².

FIGS. 3A and 3B schematically illustrate the change in colour of the part to be treated 20 once it has been subjected to the ion implantation method according to the invention. In the case of an external part for watchmaking such as the ceramic bezel 28 (see FIG. 3A), a change in colour of the metal inserts 30 is observed after the ion implantation treatment (see FIG. 3B).

It goes without saying that the present invention is not limited to the embodiment which has just been described and that various simple modifications and variants can be considered by the person skilled in the art without departing from the scope of the invention as defined by the appended claims. It should be noted in particular that by mono- or multi-charged ions is meant ions whose degree of ionisation is equal to or greater than +1. It should also be noted that the ion beam may be composed of ions all having the same degree of ionisation, or may result from a mixture of ions having different degrees of ionisation. It is also noted that in the case where, for example, the metal inserts of a ceramic bezel are treated, no masking operation is necessary: the entire surface of the bezel can be exposed to the ion beam, without this altering the mechanical properties or the appearance of the ceramic material. Only the colour of the metal inserts will change. To make the colour of the metal inserts even deeper, or even to change it, it is possible, after ion implantation treatment, to subject the part to be treated, for example the ceramic bezel with its metal inserts, to an annealing heat treatment. Also in this case, the annealing treatment will not affect the properties of the ceramic.

### NOMENCLATURE

1. ECR ion source
2. Injection stage
4. Volume of gas to be ionised
6. Microwave
8. Magnetic confinement stage
10. Plasma
12. Extraction stage
14a. Anode
14b. Cathode
16. Ion Beam
18. Surface
20. Part to be treated
22. Ion implantation installation
24. Vacuum chamber
26. Sealed enclosure
28. Bezel
30. Metallic inclusions
32. Opening

1. A method for colouring a part to be treated made of metal, said method comprising a step of implanting mono- or multi-charged ions in a surface layer of the part to be treated by directing towards said part to be treated a mono- or multi-charged ion beam produced by a source of mono- or multi-charged ions, the part to be treated changing colour under the effect of said ion implantation.

2. The colouring method according to claim 1, wherein the mono- or multi-charged ion source is an ECR ion source.

3. The colouring method according to claim 1, wherein the part to be treated is fixed on a support part insensitive to the ion implantation treatment.

4. The colouring method according to claim 2, wherein the part to be treated is fixed on a support part insensitive to the ion implantation treatment.

5. The colouring method according to claim 3, wherein the support part is a ceramic part.

6. The colouring method according to claim 4, wherein the support part is a ceramic part.

7. The colouring method according to claim 5, wherein the support part is an external part.

8. The colouring method according to claim 6, wherein the support part is an external part.

9. The colouring method according to claim 7, wherein the external part is intended for watchmaking or jewellery.

10. The colouring method according to claim 8, wherein the external part is intended for watchmaking or jewellery.

11. The colouring method according to claim 9, wherein the external part is selected from the group formed by a watch middle, a watch case back, a watch bezel, a watch dial, a watch bracelet or jewel link, a bridge or a plate of a watch movement, watch hands and a ring.

12. The colouring method according to claim 10, wherein the external part is selected from the group formed by a watch middle, a watch case back, a watch bezel, a watch dial, a watch bracelet or jewel link, a bridge or a plate of a watch movement, watch hands and a ring.

13. The colouring method according to claim 1, wherein the metal from which the part to be treated is made is selected from the group of precious metals formed by gold, silver, platinum, palladium, ruthenium, iridium and alloys of these precious metals.

14. The colouring method according to claim 1, wherein the part to be treated is made using copper, aluminium, zirconium, titanium or an alloy of these metals.

15. The colouring method according to claim 13, wherein the material to be ionised is selected from the group formed by carbon, nitrogen, oxygen, helium and argon.

16. The colouring method according to claim 14, wherein the material to be ionised is selected from the group formed by carbon, nitrogen, oxygen, helium and argon.

17. The colouring method according to claim 15, wherein the mono- or multi-charged ions are accelerated under voltages comprised between 12.5 kV and 47.5 kV, the ion beam power is comprised between 4 mA and 15 mA and the implanted ion dose is comprised between 5·10¹⁵ ions·cm⁻² and 75·10¹⁶ ions·cm⁻².

18. The colouring method according to claim 16, wherein the mono- or multi-charged ions are accelerated under voltages comprised between 12.5 kV and 47.5 kV, the ion beam power is comprised between 4 mA and 15 mA and the implanted ion dose is comprised between 5·10¹⁵ ions·cm⁻² and 75·10¹⁶ ions·cm⁻².

19. The colouring method according to claim 1, wherein the part to be treated is placed in a vacuum chamber into which the mono- or multi-charged ion beam is injected.

20. The colouring method according to claim 19, wherein, after the ion implantation treatment, the part to be treated is subjected to an annealing heat treatment.

21. A part to be treated made of metal and coloured with the colouring method according to claim 1.
